(19) United States
(12) Patent Application Publication
(10) Pub. No.: US 2023/0170848 A1
(43) Pub. Date: Jun. 1, 2023

(54) AMPLIFIER

(71) Applicant: FUJITSU LIMITED, Kawasaki-shi (JP)

(72) Inventor: Tatsuya HIROSE, Yokohama (JP)

(73) Assignee: FUJITSU LIMITED, Kawasaki-shi (JP)

(21) Appl. No.: 17/864,057

(22) Filed: Jul. 13, 2022

(30) Foreign Application Priority Data
Nov. 26, 2021 (JP) 2021-192380

(51) Int. Cl. H03F 1/02; H03F 3/21

(52) U.S. Cl. CPC H03F 1/0205; H03F 3/21

(57) ABSTRACT

An amplifier includes a first transistor in which a gate terminal is connected to an input port of a signal and a source terminal is grounded, a second transistor in which a gate terminal is grounded and a source terminal is connected to a drain terminal of the first transistor, and a harmonic wave control circuit that is connected to the gate terminal of the second transistor and that controls a high harmonic wave component that is produced when the signal that is input from the input port is amplified.

### CROSS-REFERENCE TO RELATED APPLICATION

This application is based upon and claims the benefit of priority of the prior Japanese Patent Application No. 2021-192380, filed on Nov. 26, 2021, the entire contents of which are incorporated herein by reference.

### FIELD

The embodiment discussed herein is related to an amplifier.

### BACKGROUND

In recent years, with a development of large capacity transmission in the communication field, impact thereof also spreads in the field of, for example, wireless communication. Specifically, for example, in the fifth generation mobile communication system (5G), wireless communication apparatuses that is able to be used in wider bandwidth are needed. Furthermore, the frequency of carrier to be used is higher and a power loss of an amplifier that amplifies signals is accordingly increased, so that power efficiency of the wireless communication apparatuses is degraded.

One of the causes of increasing the power loss of the amplifier is conceived that the electrical power gain, such as the unilateral power gain and the maximum available power gain, and the electric current gain that are used to amplify the signals are decreased in accordance with an increase in the frequency of the signal.

Incidentally, in recent years, the performance of metal-oxide-semiconductor (MOS) transistors (Si-MOS transistors) using a silicon (Si) material is improved, and thus, the Si-MOS transistors are also actively used in the field of wireless communication. For example, if the Si-MOS transistor is used for an amplifier included in a wireless communication apparatus, the maximum oscillation frequency or the high cutoff frequency of this transistor needs to be about 3 to 5 times larger than the carrier frequency. As a result, in some cases, a transistor in which a gate length is reduced is used; however, a power supply voltage that is able to be applied to the transistor is decreased in accordance with the reduction in the gate length. Accordingly, in order to obtain a desired output power, an amplifier that is able to use a high power supply voltage is sometimes configured by using a cascode configuration in which a grounded source transistor and a grounded gate transistor are connected in series.

Patent Document 1: Japanese National Publication of International Patent Application No. 2004-516737

However, in the amplifier having the cascode configuration, there is a problem in that a power loss is increased. Specifically, if signal power that is input to the transistor is increased, a high harmonic wave having a frequency that is an integral multiple of the carrier frequency is generated as a result of depending on nonlinearity of the electric current voltage characteristics of the transistor. The high harmonic wave is an unneeded signal, so that, for example, a filter circuit that blocks transmission of the high harmonic wave signal is sometimes provided on a signal path. In general, this type of filter circuit is constituted by using a passive element, such as a condenser and an inductor, having electric resistance, so that, if a signal passes through the filter circuit, signal power is converted to heat and a power loss is produced.

As described above, if the circuit that is used to block the transmission of the high frequency signal is constituted on the signal path, in addition to the power loss produced due to an increase in the carrier frequency described above, even larger power loss is produced, and thus, power efficiency of the wireless communication apparatus is considerably decreased.

### SUMMARY

According to an aspect of an embodiment, an amplifier includes a first transitor in which a gate terminal is connected to an input port of a signal and a source terminal is grounded. The amplifier includes a second transistor in which a gate terminal is grounded and a source terminal is connected to a drain terminal of the first transistor. The amplifier includes a harmonic wave control circuit that is connected to the gate terminal of the second transistor and that controls a high harmonic wave component that is produced when the signal that is input from the input port is amplified.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a configuration of a cascode amplifier;

FIG. 2 is a diagram illustrating an amplifier according to an embodiment;

FIG. 3 is a diagram illustrating the characteristics of a transistor;

FIG. 4 is a diagram illustrating the other characteristics of the transistor;

FIG. 5 is a diagram illustrating a configuration example of a harmonic wave control circuit;

FIG. 6 is a diagram illustrating frequency characteristics of the harmonic wave control circuit;

FIG. 7 is a diagram illustrating another configuration example of the harmonic wave control circuit;

FIG. 8 is a diagram illustrating a specific example of input and output waveforms;

FIG. 9 is a diagram illustrating a specific example of output power characteristics;

FIG. 10 is a diagram illustrating a specific example of gain-output power characteristics;

FIG. 11 is a diagram illustrating a modification of the harmonic wave control circuit;

FIG. 12 is a diagram illustrating another modification of the harmonic wave control circuit;

FIG. 13 is a diagram illustrating a specific example of frequency characteristics in the vicinity of a third harmonic wave; and

FIG. 14 is a diagram illustrating a modification of the amplifier.

### DESCRIPTION OF EMBODIMENTS

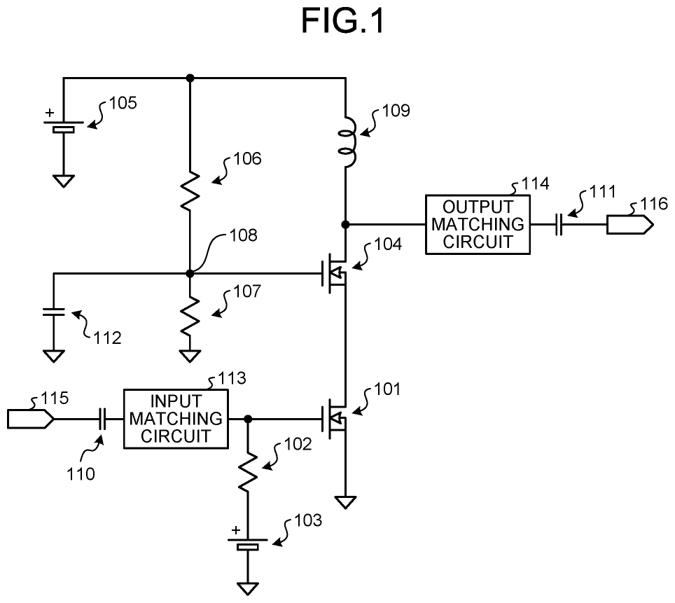

Preferred embodiments of the present invention will be explained with reference to accompanying drawings. Before an embodiment of an amplifier disclosed in the present application is described, an amplifier that uses a cascode configuration will be described. FIG. 1 is a diagram illustrating a configuration of the cascode amplifier. The cascode amplifier illustrated in FIG. 1 amplifies a signal that is input from an input port 115 and then outputs the amplified signal from an output port 116. A grounded source transistor 101 and a grounded gate transistor 104 are connected in series on the signal path, and the cascode configuration is used.

The signal that is input from the input port 115 is output from the output port 116 by passing through a condenser 110, an input matching circuit 113, the grounded source transistor 101, the grounded gate transistor 104, an output matching circuit 114, and a condenser 111. A gate voltage of the grounded source transistor 101 is supplied from a power supply 103 via a resistor 102, whereas a gate voltage of the grounded gate transistor 104 is supplied as a result of a voltage of a power supply 105 connecting a node 108, which is divided by resistors 106 and 107, to a gate terminal of the grounded gate transistor 104.

A positive terminal of the gate direct current power supply 103 in which a negative terminal is grounded and that applies a gate voltage is connected to a gate terminal of the grounded source transistor 101 via the resistor 102. Furthermore, the source terminal of the grounded source transistor 101 is grounded, and the drain terminal is connected to the source terminal of the grounded gate transistor 104. One of the terminals of the inductor 109 that is used to block an alternating current signal is connected to the drain terminal of the grounded gate transistor 104, and the other of the terminals of the inductor 109 is connected to the positive terminal of the power supply 105 and the resistor 106. The gate terminal of the grounded gate transistor 104 is connected to the node 108 located between the resistors 106 and 107, and is then connected to a condenser 112 that is used to short circuit the alternating current signal.

Furthermore, the cascode amplifier is configured such that the input matching circuit 113 is connected to the gate terminal of the grounded source transistor 101 and a signal that is input from the input port 115 via the direct-current blocking condenser 110 is input to the input matching circuit 113. In contrast, the cascode amplifier is configured such that the output matching circuit 114 is connected to the drain terminal of the grounded gate transistor 104 and a signal that is output from the output matching circuit 114 is output from the output port 116 via the direct-current blocking condenser 111.

If a signal is input from the input port 115, the signal is input to the input matching circuit 113 via the direct-current blocking condenser 110. In the input matching circuit 113, matching is performed such that the gain obtained at a desired frequency is the maximum, and then, the signal that is output from the input matching circuit 113 is input to the gate terminal of the grounded source transistor 101.

The signal that is input to the gate terminal of the grounded source transistor 101 allows the electric potential of the drain terminal of the grounded source transistor 101 to be changed and allows the electric current that is output from and input to the drain terminal to be changed. The drain terminal of the grounded source transistor 101 is connected to the source terminal of the grounded gate transistor 104, so that the electric potential between the gate terminal and the source terminal of the grounded gate transistor 104 is changed as a result of a change in the electric potential of the drain terminal of the grounded source transistor 101. At this time, the alternating current signal is able to be short circuited as a result of the condenser 112 being connected to the gate terminal of the grounded gate transistor 104.

As a result of the change in the electric potential between the gate terminal and the source terminal of the grounded gate transistor 104, the electric potential of the drain terminal of the grounded gate transistor 104 is changed, and the drain electric current is input to the output matching circuit 114 as a signal. In the output matching circuit 114, matching is performed such that the gain obtained at a desired frequency is the maximum, and the signal that is output from the output matching circuit 114 is output from the output port 116 via the direct-current blocking condenser 111.

At this time, if the electrical power of the input signal is increased, voltage dependency of the drain electric current of each of the grounded source transistor 101 and the grounded gate transistor 104 becomes nonlinear, and a waveform is distorted as a result of a high harmonic wave component being included in the signal that is output from the output port 116. In order to suppress the high harmonic wave component, it is conceivable to insert a filter circuit and a harmonic wave control circuit to, for example, the output matching circuit 114 disposed on the signal path. However, if these circuits are inserted on the signal path through which a drain electric current flows as a signal, the signal power is converted to heat and a power loss is produced. In other words, there is a problem in that a power loss is increased in the cascode amplifier.

Preferred embodiments of an amplifier according to the present application will be explained in detail below with reference to the accompanying drawings. Furthermore, the present invention is not limited to the embodiments.

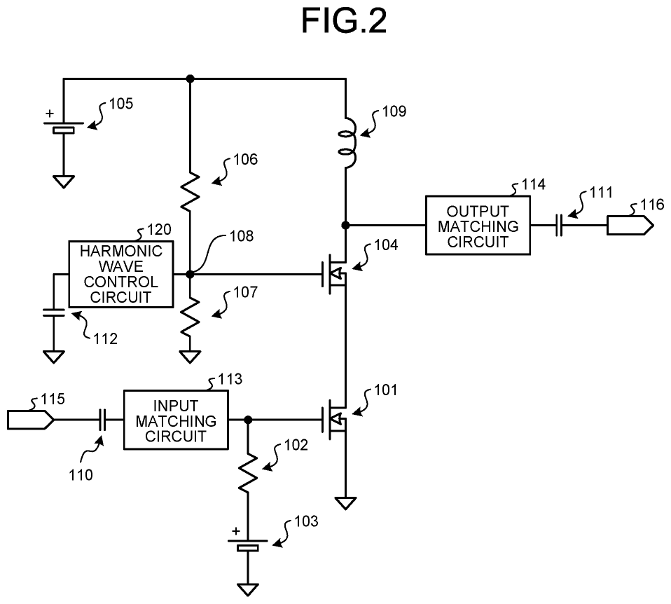

FIG. 2 is a diagram illustrating a configuration of an amplifier according to an embodiment. In FIG. 2, components that are the same as those illustrated in FIG. 1 are assigned the same reference numerals. The amplifier illustrated in FIG. 2 has a configuration in which a harmonic wave control circuit 120 is added to the cascode amplifier illustrated in FIG. 1. The harmonic wave control circuit 120 is connected to the gate terminal of the grounded gate transistor 104 instead of being disposed on the signal path. In other words, the harmonic wave control circuit 120 is provided between the condenser 112 and the node 108.

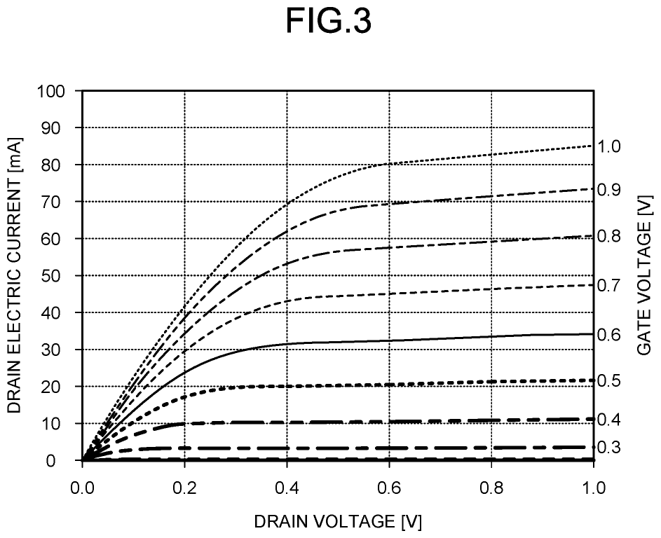

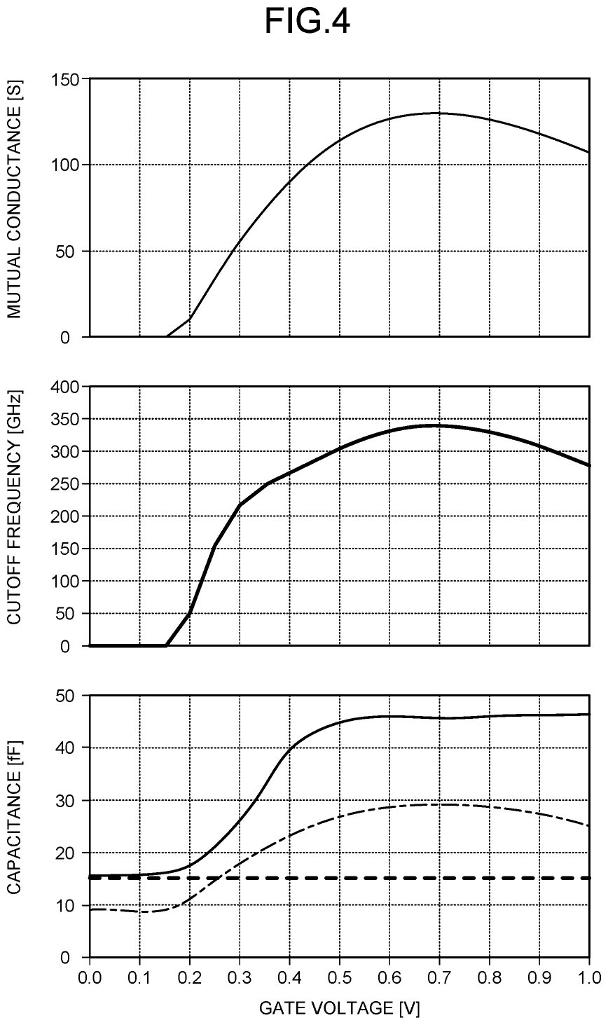

The amplifier illustrated in FIG. 2 is an amplifier that amplifies a signal having a frequency of, for example, 28 GHz. The characteristics of the grounded source transistor 101 and the grounded gate transistor 104 at this time are illustrated in FIGS. 3 and 4. In other words, FIG. 3 indicates the characteristics of a drain electric current and a voltage for each gate voltage. In addition, the upper part of FIG. 4 indicates mutual conductance for each gate voltage, the middle part of FIG. 4 indicates a cutoff frequency for each gate voltage, and the lower part of FIG. 4 indicates electric capacitance between the terminals for each gate voltage. In the lower part of FIG. 4, the solid line indicates electric capacitance between the gate-source terminals, the broken line indicates electric capacitance between gate-drain terminals, and the dashed line indicates electric capacitance between drain-source terminals. Furthermore, the maximum oscillation frequency of each of the grounded source transistor 101 and the grounded gate transistor 104 is 270 GHz.

By connecting the grounded source transistor 101 and the grounded gate transistor 104 having the characteristics described above in series, it is possible to amplify the signal having a frequency of 28 GHz.

A description will be given here by referring back to FIG. 2. The input matching circuit 113 is configured such that a shunt condenser is connected to a node that is disposed between, for example a condenser and an inductor that are connected in series. Similarly, the output matching circuit 114 is configured such that a shunt condenser is connected to a node that is disposed between, for example, a condenser and an inductor that are connected in series.

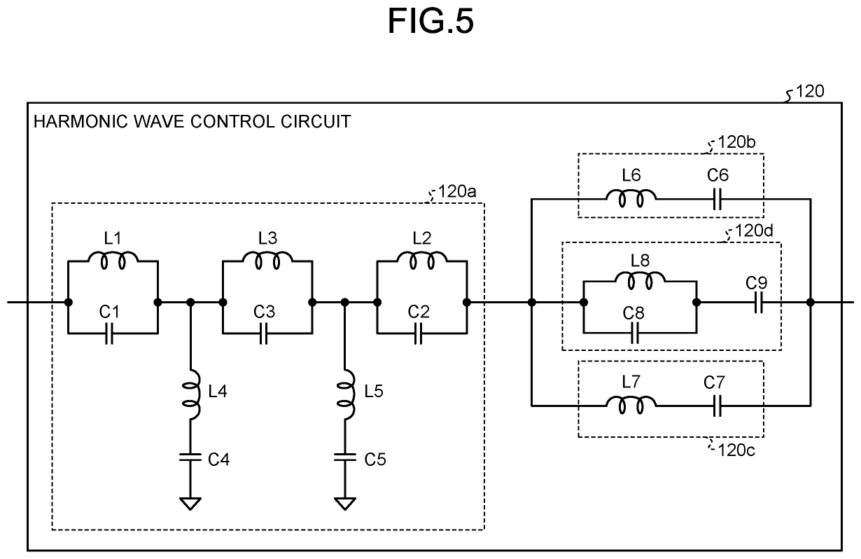

The harmonic wave control circuit 120 is configured by using, in combination, a series circuit in which an inductor that is an induction element and a condenser that is a capacitive element are connected in series and a parallel circuit in which an inductor and a condenser are connected in parallel. Then, the harmonic wave control circuit 120 outputs a fundamental wave having the same frequency as that of the input signal and performs control of the gate voltage of the grounded gate transistor 104 such that a part of a third harmonic wave is suppressed by suppressing a second harmonic wave. Specifically, the harmonic wave control circuit 120 has a configuration illustrated in, for example, FIG. 5. In other words, the harmonic wave control circuit 120 includes a second harmonic wave removal filter 120a, a third harmonic wave series resonant circuit 120b, a fundamental wave series resonant circuit 120c, and a second harmonic wave parallel resonant circuit 120d.

The second harmonic wave removal filter 120a is a band stop filter that suppresses a second harmonic wave signal of an arbitrary frequency band having the center frequency of a second harmonic wave frequency (56 GHz in this case). The second harmonic wave removal filter 120a is configured by using, in combination, a series circuit and a parallel circuit each having a condenser and an inductor that block transmission of the second harmonic wave signal. In other words, the second harmonic wave removal filter 120a is configured such that a parallel circuit constituted by a condenser C1 and an inductor L1, a parallel circuit constituted by a condenser C3 and an inductor L3, and a parallel circuit constituted by a condenser C2 and an inductor L2 are connected in series, and a series circuit constituted by a condenser C4 and an inductor L4 and a series circuit constituted by a condenser C5 and an inductor L5 are connected between the parallel circuits in this order described in this sentence. Furthermore, the number of series circuits and parallel circuits each having the condenser and the inductor is not limited to the number illustrated in FIG. 5. For example, it may be configured by deleting the series circuit constituted by the condenser C5 and the inductor L5 and the parallel circuit constituted by the condenser C2 and the inductor L2, or it may be configured by adding another series circuit and another parallel circuit each having a condenser and an inductor.

The third harmonic wave series resonant circuit 120b is a series resonant circuit that resonates with a frequency of a third harmonic wave (84 GHz in this case). In other words, the third harmonic wave series resonant circuit 120b is configured such that a condenser C6 and an inductor L6 are connected in series. The third harmonic wave series resonant circuit 120b allows the third harmonic wave signal to pass after suppressing a part of the third harmonic wave signal.

The fundamental wave series resonant circuit 120c is a series resonant circuit that resonates with a frequency of a fundamental wave (28 GHz in this case). In other words, the fundamental wave series resonant circuit 120c is configured such that a condenser C7 and an inductor L7 are connected in series. The capacitance and the inductance of the condenser C7 and the inductor L7 are three times as large as the capacitance and the inductance of the condenser C6 and the inductor L6, respectively. The fundamental wave series resonant circuit 120c allows the fundamental wave signal to pass after suppressing a part of the fundamental wave signal.

The second harmonic wave parallel resonant circuit 120d is a parallel resonant circuit that resonates with a frequency of a second harmonic wave (56 GHz in this case). In other words, the second harmonic wave parallel resonant circuit 120d is configured such that a condenser C8 and an inductor L8 are connected in parallel, and a condenser C9 that is used to remove a direct current component is connected. The second harmonic wave parallel resonant circuit 120d adjusts the band edge of the second harmonic wave signal that has been suppressed by the second harmonic wave removal filter 120a.

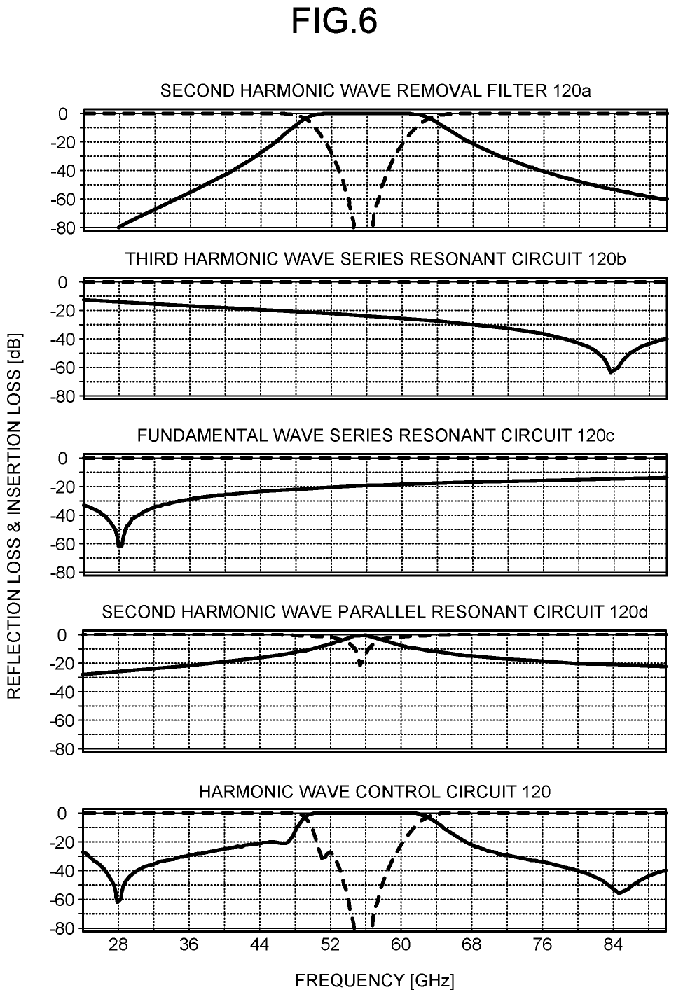

The frequency characteristic of each of the second harmonic wave removal filter 120a, the third harmonic wave series resonant circuit 120b, the fundamental wave series resonant circuit 120c, and the second harmonic wave parallel resonant circuit 120d and the frequency characteristic of the harmonic wave control circuit 120 are illustrated in FIG. 6. FIG. 6 indicates a reflection loss (S11 parameter) of each of the circuits indicated by the solid line and indicates an insertion loss (S21 parameter) indicated by the broken line.

As illustrated in FIG. 6, the second harmonic wave is suppressed by each of the second harmonic wave removal filter 120a and the second harmonic wave parallel resonant circuit 120d, and a part of each of the third harmonic wave and the fundamental wave is suppressed by each of the third harmonic wave series resonant circuit 120b and the fundamental wave series resonant circuit 120c, and is then allowed to pass. As a result, as illustrated in the lowest part of FIG. 6, the harmonic wave control circuit 120 outputs the fundamental wave signal, and also, suppresses a part of the third harmonic wave signal by suppressing the second harmonic wave signal. Then, as a result of these signals being input to the gate terminal of the grounded gate transistor, the fundamental wave is output from the drain terminal of the grounded gate transistor 104 and a part of the third harmonic wave is suppressed as a result of the second harmonic wave being suppressed. Consequently, a high harmonic wave component of the output signal is suppressed, so that it is possible to increase the output power of the fundamental wave component. Furthermore, the harmonic wave control circuit 120 that is used to suppress the high harmonic wave component is not provided on the signal path, a power loss of the signal caused by the harmonic wave control circuit 120 is not produced, so that it is possible to prevent an increase in power loss.

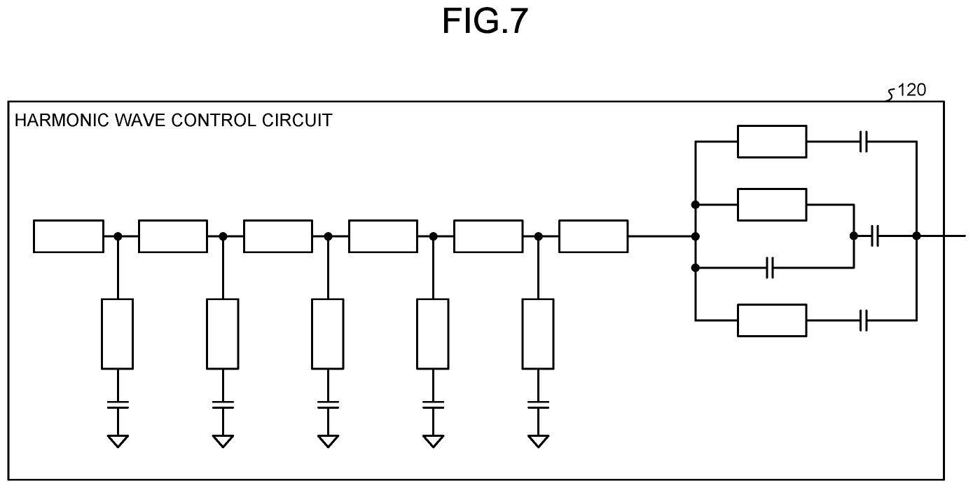

Furthermore, the harmonic wave control circuit 120 may be configured to use a distribution constant line as illustrated in, for example, FIG. 7 instead of using a passive element, such as a condenser and an inductor.

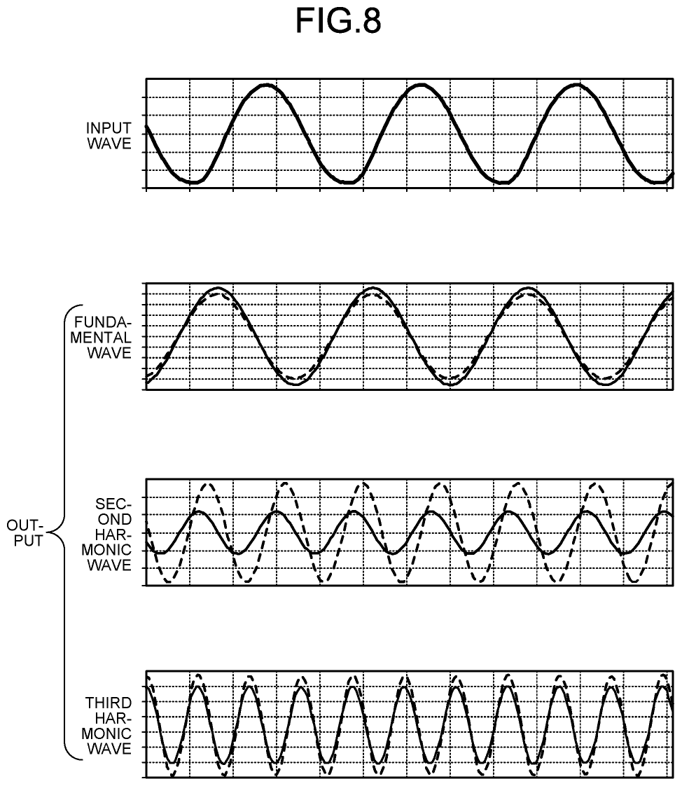

In the following, an output signal of each of the cascode amplifier illustrated in FIG. 1 and the amplifier illustrated in FIG. 2 will be described with reference to FIGS. 8 to 10.

FIG. 8 is a diagram illustrating a specific example of an input waveform and output waveforms that are input to and output from the amplifier. In FIG. 8, the solid line indicates the output waveform that is output from the amplifier illustrated in FIG. 2, whereas the broken line indicates the output waveform that is output from the cascode amplifier illustrated in FIG. 1.

The uppermost part of FIG. 8 indicates an input waveform. The frequency of the input waveform is 28 GHz. If the signal having this input waveform is input to the amplifier, as illustrated by the broken line on the third and the fourth part of FIG. 8, a high harmonic wave component, such as a second harmonic wave and a third harmonic wave, is output from the cascode amplifier that does not include the harmonic wave control circuit 120 illustrated in FIG. 1 without being suppressed. In contrast, in the amplifier that includes the harmonic wave control circuit 120 illustrated in FIG. 2, the second harmonic wave is suppressed and, in addition, a part of the third harmonic wave is suppressed, so that the electrical power of the fundamental wave is increased by an amount equal to the suppression. In other words, the amplifier having the harmonic wave control circuit 120 is able to implement high gain.

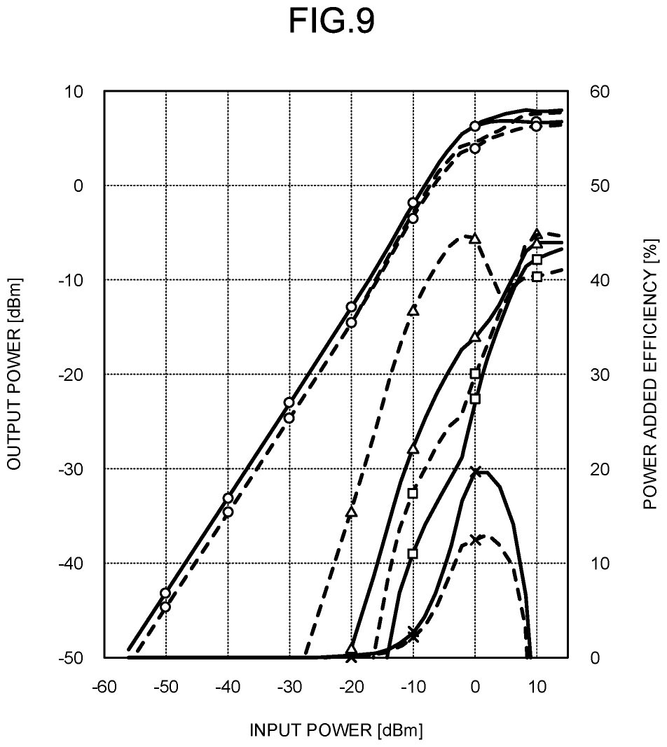

FIG. 9 is a diagram illustrating a specific example of the output power characteristics of the amplifier. In FIG. 9, the solid line indicates output power of the amplifier illustrated in FIG. 2, and the broken line indicates output power of the cascode amplifier illustrated in FIG. 1. Furthermore, the line without a mark indicates the electrical power of the output signal, the line with a circle mark indicates output power of the fundamental wave, the line with a triangle mark indicates output power of the second harmonic wave, the line with a square mark indicates output power of the third harmonic wave, and the line with a cross mark indicates power added efficiency (PAE).

As illustrated in FIG. 9, by providing the harmonic wave control circuit 120, in particular, the second harmonic wave is largely suppressed (by an amount about 12 dB), a linear area in which the electrical power of the input signal and the electrical power of the output signal has linearity is increased. In other words, distortion of the output signal is reduced as a result of the high harmonic wave component being suppressed by the harmonic wave control circuit 120. Furthermore, by providing the harmonic wave control circuit 120, the power added efficiency has been improved by a factor of about 1.5.

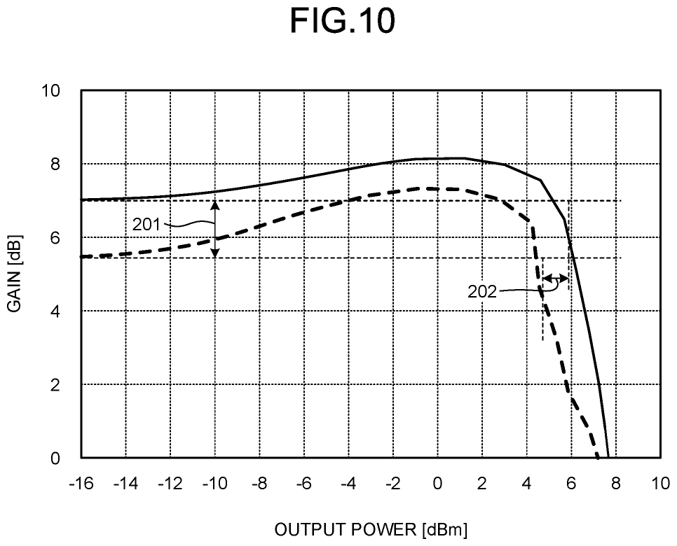

FIG. 10 is a diagram illustrating a specific example of the gain-output power characteristic. In FIG. 10, the solid line indicates the gain and the output power of the amplifier illustrated in FIG. 2, whereas the broken line indicates the gain and the output power of the cascode amplifier illustrated in FIG. 1.

As illustrated in FIG. 10, the gain of the amplifier having the harmonic wave control circuit 120 is high at the output power, a difference 201 between the gains is about, for example, 1.5 dB. Furthermore, the 1 dB gain compression point (P1dB) is also improved by the amplifier that includes the harmonic wave control circuit 120 and an improved width 202 is about, for example, 1.6 dBm.

As described above, according to the present embodiment, in the amplifier having a cascode configuration in which the grounded source transistor and the grounded gate transistor are connected in series, the harmonic wave control circuit is connected to the gate terminal of the grounded gate transistor. Then, the harmonic wave control circuit controls the gate voltage of the grounded gate transistor such that the fundamental wave is output and a part of the third harmonic wave is suppressed as a result of the second harmonic wave being suppressed. As a result, it is possible to reduce distortion of the output signal as a result of the high harmonic wave component being suppressed, and, in addition, a power loss of the signal is not produced because the harmonic wave control circuit is not provided on the signal path. Consequently, it is possible to prevent an increase in power loss.

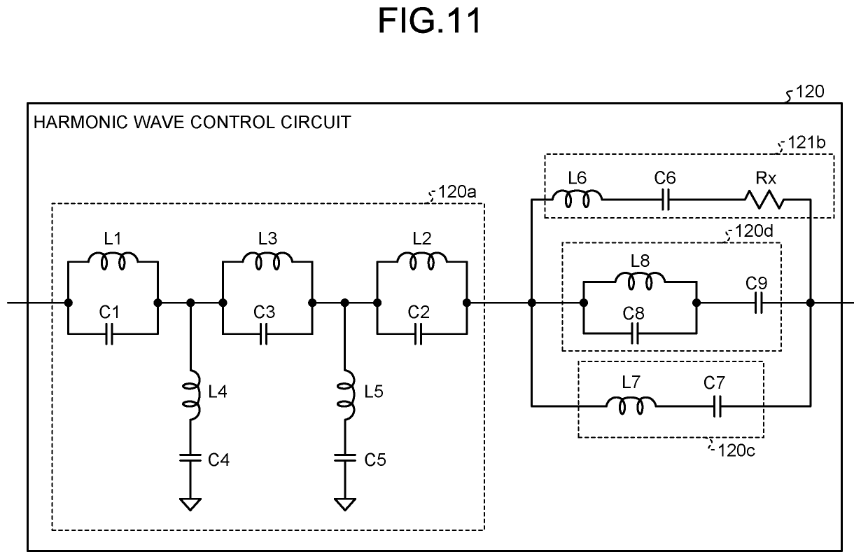

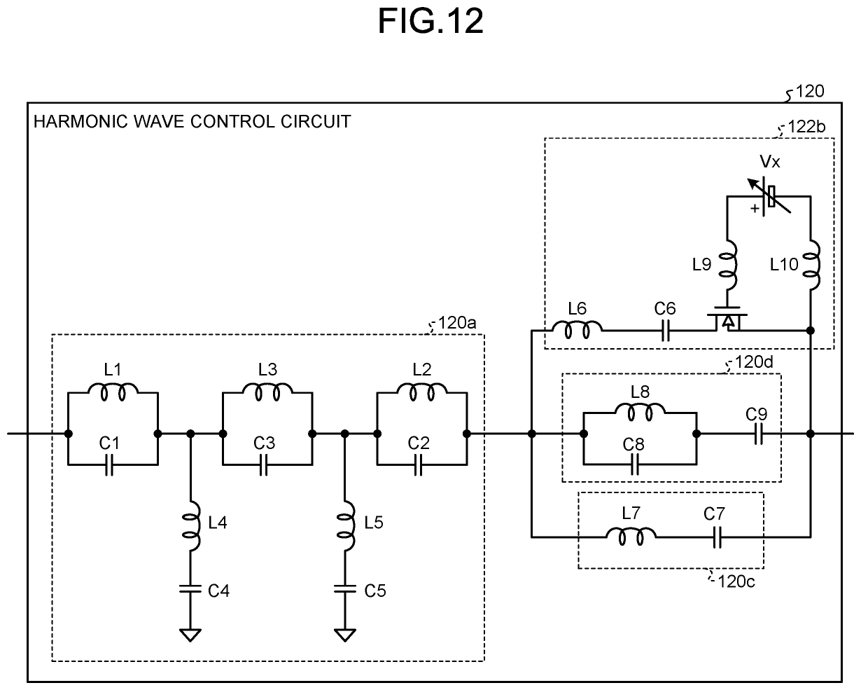

Furthermore, it is also possible to adjust linearity of the output power by adjusting an amount of suppression of the third harmonic wave by using the harmonic wave control circuit 120. Specifically, FIGS. 11 and 12 are diagrams each illustrating a modification of the harmonic wave control circuit 120. In FIGS. 11 and 12, components that are the same as those illustrated in FIG. 5 are assigned the same reference numerals. The harmonic wave control circuit 120 illustrated in FIG. 11 includes a third harmonic wave series resonant circuit 121b instead of the third harmonic wave series resonant circuit 120b included in the harmonic wave control circuit 120 illustrated in FIG. 5. Furthermore, the harmonic wave control circuit 120 illustrated in FIG. 12 includes a third harmonic wave series resonant circuit 122b instead of the third harmonic wave series resonant circuit 120b included in the harmonic wave control circuit 120 illustrated in FIG. 5.

The third harmonic wave series resonant circuit 121b is configured such that a resistor Rx is connected to the condenser C6 and the inductor L6 in series. In contrast, the third harmonic wave series resonant circuit 122b is configured such that a transistor is connected to the condenser C6 and the inductor L6 in series. The transistor is driven by an external voltage Vx connected via inductors L9 and L10 and operates as variable resistance.

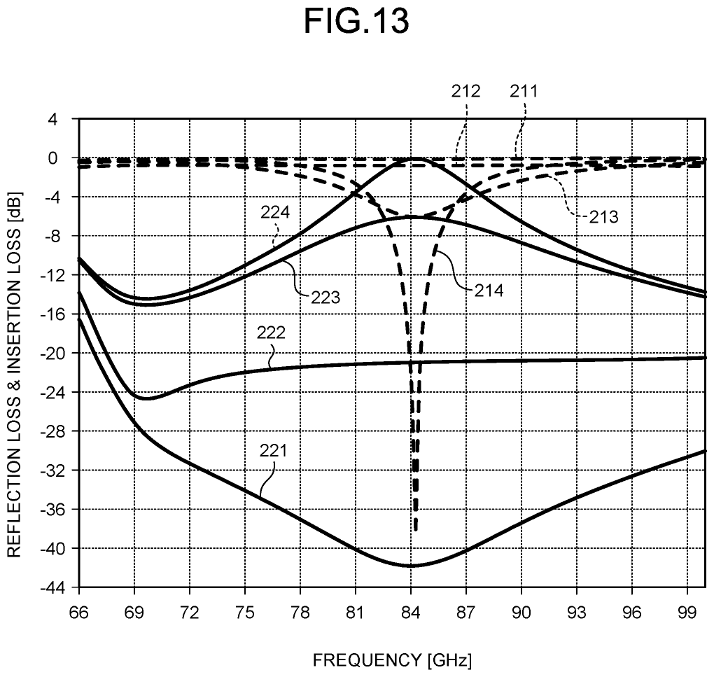

As described above, by adding a resistance element to each of the third harmonic wave series resonant circuits 121b and 122b and adjusting the resistance of the resistance elements, it is possible to control an amount of suppression of the third harmonic wave. Specifically, the frequency characteristic exhibited in the vicinity of the third harmonic wave in the case where the resistor Rx illustrated in, for example, FIG. 11 is defined to be 1 Ω, 10 Ω, 100 Ω, and 10 k Ω is illustrated in FIG. 13. FIG. 13 is a diagram illustrating a reflection loss (S11 parameter) indicated by the solid line and a insertion loss (S21 parameter) indicated by the broken line in the case where the value of the resistor Rx is 1 Ω, 10 Ω, 100 Ω, and 10k Ω.

In other words, curved lines 211 and 221 each indicate an insertion loss and a reflection loss in the case where the resistor Rx is 1 Ω, curved lines 212 and 222 each indicate an insertion loss and a reflection loss in the case where the resistor Rx is 10 Ω, curved lines 213 and 223 each indicate an insertion loss and a reflection loss in the case where the resistor Rx is 100 Ω, and curved lines 214 and 224 each indicate an insertion loss and a reflection loss in the case where the resistor Rx is 10k Ω. As illustrated in FIG. 13, an amount of suppression of the third harmonic wave is changed as a result of a change in the value of the resistor Rx, and the gate voltage applied to the grounded gate transistor 104 is also changed. Consequently, it is possible to adjust the electrical power of the output signal of the amplifier and it is thus possible to adjust the linearity of the output power.

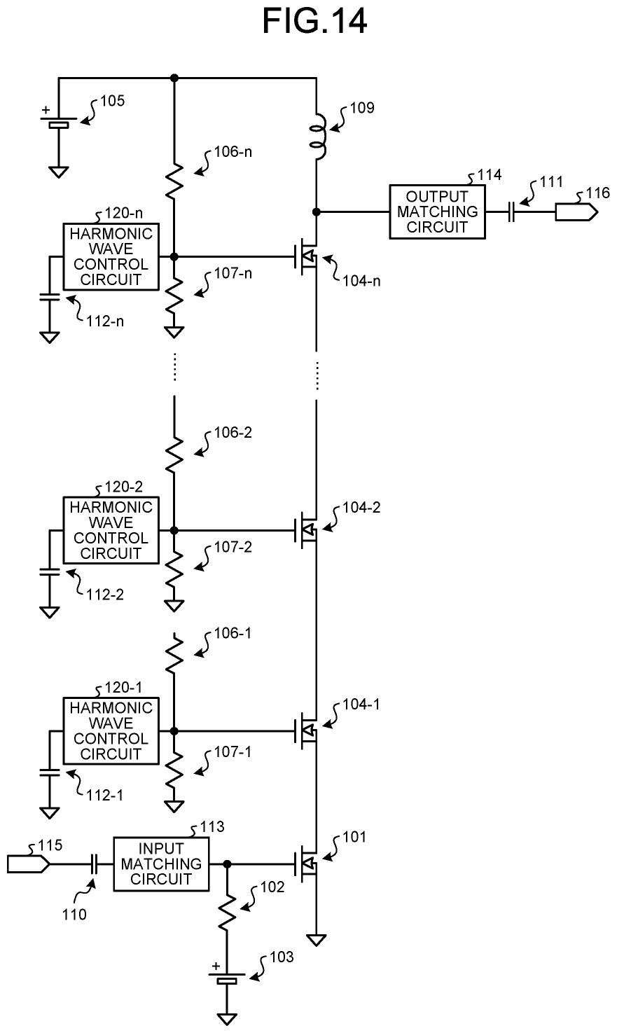

Furthermore, in one embodiment described above, a case has been described as an example in which the amplifier is configured such that the single grounded gate transistor 104 is connected to the grounded source transistor 101; however, it may be possible to configure the amplifier such that a plurality of the grounded gate transistors 104 are connected to the grounded source transistor 101. FIG. 14 is a diagram illustrating a configuration of an amplifier in the case where n grounded gate transistors 104-1 to 104-n (n is an integer equal to or greater than 2) are connected to the grounded source transistor 101. As illustrated in FIG. 14, harmonic wave control circuits 120-1 to 120-n are connected to the gate terminals of the n grounded gate transistors 104-1 to 104-n together with condensers 112-1 to 112-n that short circuit each of the alternating current signals. The gate voltage of each of the grounded gate transistors 104-1 to 104-n is supplied by dividing the voltage of the power supply 105 by the resistors 106-1 to 106-n and 107-1 to 107-n, respectively.

According to an aspect of an embodiment of the amplifier disclosed in the present application, an advantage is provided in that it is possible to prevent an increase in power loss.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. An amplifier comprising:
a first transistor in which a gate terminal is connected to an input port of a signal and a source terminal is grounded;
a second transistor in which a gate terminal is grounded and a source terminal is connected to a drain terminal of the first transistor; and
a harmonic wave control circuit that is connected to the gate terminal of the second transistor and that controls a high harmonic wave component that is produced when the signal that is input from the input port is amplified.

2. The amplifier according to claim 1, wherein the harmonic wave control circuit includes
a series circuit in which an induction element and a capacitive element are connected in series, and
a parallel circuit in which an induction element and a capacitive element are connected in parallel.

3. The amplifier according to claim 1, wherein the harmonic wave control circuit includes
a second harmonic wave removal filter that suppresses a second harmonic wave of the signal that is input from the input port,
a third harmonic wave series resonant circuit that resonates with a third harmonic wave of the signal that is input from the input port and that includes an induction element and a capacitive element that are connected in series,
a fundamental wave series resonant circuit that resonates with a fundamental wave of the signal that is input from the input port and that includes an induction element and a capacitive element that are connected in series, and
a second harmonic wave parallel resonant circuit that resonates with the second harmonic wave of the signal that is input from the input port and that includes an induction element and a capacitive element that are connected in parallel.

4. The amplifier according to claim 3, wherein the third harmonic wave series resonant circuit includes the induction element, the capacitive element, and a resistance element that are connected in series.

5. The amplifier according to claim 3, wherein the third harmonic wave series resonant circuit includes the induction element, the capacitive element, and a third transistor that are connected in series.

6. The amplifier according to claim 3, wherein the second harmonic wave removal filter includes
a first parallel circuit in which an induction element and a capacitive element are connected in parallel,
a second parallel circuit that is connected to the first parallel circuit in series and in which an induction element and a capacitive element are connected in parallel, and
a series circuit in which an induction element and a capacitive element are connected in series, one end of the series circuit is grounded, and another end of the series circuit is connected at a position located between the first parallel circuit and the second parallel circuit.
